(19) United States
(12) Patent Application Publication
(10) Pub. No.: US 2017/0076976 A1
(43) Pub. Date: Mar. 16, 2017

(54) ISOLATION STRUCTURE AND METHOD FOR FABRICATING THE SAME

(71) Applicant: MACRONIX International Co., Ltd., Hsinchu (TW)

(72) Inventors: Chin-Tsan Yeh, Hsinchu (TW); Tuung Luoh, Hsinchu (TW); Ta-Hung Yang, Hsinchu (TW); Kuang-Chao Chen, Hsinchu (TW)

(21) Appl. No.: 14/855,815

(22) Filed: Sep. 16, 2015

(51) Int. Cl. H01L 21/762; H01L 29/06

(52) U.S. Cl. CPC H01L 21/76232; H01L 29/0649

(57) ABSTRACT

An isolation structure and a method of fabricating the same are provided. The isolation structure includes a buffer layer and an encapsulation layer. The buffer layer is located in a trench of a substrate. The encapsulation layer is located in the trench and encapsulates around the buffer layer, wherein the buffer layer is unexposed and is not in contacted with the trench. A material of the buffer layer is different from a material of the encapsulation layer.

### BACKGROUND OF THE INVENTION

1. Field of the Invention

The invention relates to an isolation structure and a method for fabricating the same.

2. Description of Related Art

As semiconductor devices are integrated, in order to achieve high density and high performance, it is preferred to form a smaller and higher integrated structure when fabricating the semiconductor devices. Therefore, the isolation effects of the isolation structure influence the performance of the semiconductor devices becomes larger.

In the process of manufacturing the semiconductor devices, the formation of the isolation structure may be influenced by the subsequent processes so as to generate problems such as lattice dislocations or bridge defects. Such problems may be one of the reasons result in the leakage current generated from the semiconductor devices. Thus, how to form an isolation structure to reduce the above mentioned problems in lattice dislocations or bridge defects are certainly an issue to work on.

### SUMMARY OF THE INVENTION

The invention provides an isolation structure and a method of fabricating the same which may reduce the problems in lattice dislocations or bridge defects, further achieve a proper filling-gap ability.

The invention provides an isolation structure. The isolation structure includes a buffer layer and an encapsulation layer. The buffer layer is located in a trench of a substrate. The encapsulation layer is located in the trench and encapsulates around the buffer layer, wherein the buffer layer is unexposed and is not in contacted with the trench, and a material of the buffer layer is different from a material of the encapsulation layer.

According to an embodiment of the invention, a shape of the buffer layer is a U shape or a V shape.

According to an embodiment of the invention, the buffer layer includes a single-layer structure or a multi-layer structure.

According to an embodiment of the invention, the material of the buffer layer includes silicon nitride, silicon oxynitride, or a combination thereof.

According to an embodiment of the invention, a ratio of a height of the buffer layer and a width of the trench is in a range of 20% to 90%.

The invention provides an isolation structure. The isolation structure includes a liner layer, a buffer layer, a first insulation layer, and a second insulation layer. The liner layer is located on a bottom surface and sidewalls of a trench of a substrate. The buffer layer is located on a bottom surface and a portion of sidewalls of the liner layer, wherein another portion of sidewalls of the liner layer is exposed. The first insulation layer is located on a bottom surface and sidewalls of the buffer layer. The second insulation layer is located on a top surface of the first insulation layer, a top surface of the buffer layer, and the another portion of sidewalls of the liner layer.

According to an embodiment of the invention, a shape of the buffer layer is a U shape or a V shape.

According to an embodiment of the invention, the buffer layer includes a single-layer structure or a multi-layer structure.

According to an embodiment of the invention, a material of the buffer layer is different from a material of the liner layer.

According to an embodiment of the invention, a material stress of the buffer layer is larger than a material stress of the liner layer.

According to an embodiment of the invention, the material of the buffer layer includes silicon nitride, silicon oxynitride, or a combination thereof.

According to an embodiment of the invention, a thickness of the buffer layer is in a range of 100 angstroms to 200 angstroms.

According to an embodiment of the invention, a ratio of a height of the buffer layer and a width of the trench is in a range of 20% to 90%.

According to an embodiment of the invention, a material of the first insulation layer and a material of the second insulation layer respectively include oxides, spin-on dielectric materials, or a combination thereof.

The invention provides a method of fabricating an isolation structure, including the following steps. A trench is formed in a substrate. A liner layer is formed. The liner layer covers a bottom surface and sidewalls of the trench. A buffer layer is formed. The buffer layer covers a surface of the liner layer. A first insulation layer is formed. The first insulation layer covers a surface of the buffer layer. A portion of the first insulation layer and a portion of the buffer layer are removed to expose a portion of sidewalls of the liner layer on the sidewalls of the trench. A second insulation layer is formed. The second insulation layer covers a top surface of the first insulation layer, a top surface of the buffer layer, and the portion of sidewalls of the liner layer.

According to an embodiment of the invention, a material stress of the buffer layer is larger than a material stress of the liner layer.

According to an embodiment of the invention, after removing the portion of the first insulation layer and the portion of the buffer layer, a ratio of a height of the buffer layer and a width of the trench is in a range of 20% to 90%.

According to an embodiment of the invention, a method to remove the portion of the first insulation layer and the portion of the buffer layer includes a dry etching process, a wet etching process, or a combination thereof.

According to an embodiment of the invention, an etching gas of the dry etching process includes nitrogen trifluoride (NF₃).

According to an embodiment of the invention, an etching liquid of the wet etching process includes phosphoric acid (H₃PO₄), hydrofluoric acid (HF), or a combination thereof.

Based on the above, in the invention, formation of the isolation structure with the buffer layer having a larger material stress as a stress buffer layer between the substrate and the insulation layer, in the subsequent high temperature process, a leakage current arising from structure deformation due to a volume expansion of the insulation layer in the trench can be avoided. Furthermore, due to the buffer layer may reduce the aspect ratio of the trench, it may achieve a proper gap-filling ability. In addition, by regulating the parameters of the process, a suitable height, thickness, and profile of the buffer layer of the invention may be formed. In this way, the problems in bridge defects may be avoided. Furthermore, the semiconductor devices with the isolation structure have the better electron mobility. Therefore, the electrical performance and the yield of the semiconductor devices can be improved.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1G are schematic cross-sectional views illustrating a method of fabricating an isolation structure according to an embodiment of the invention.

FIG. 2 is a leakage current test of isolation structures manufactured according to examples and comparative examples of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

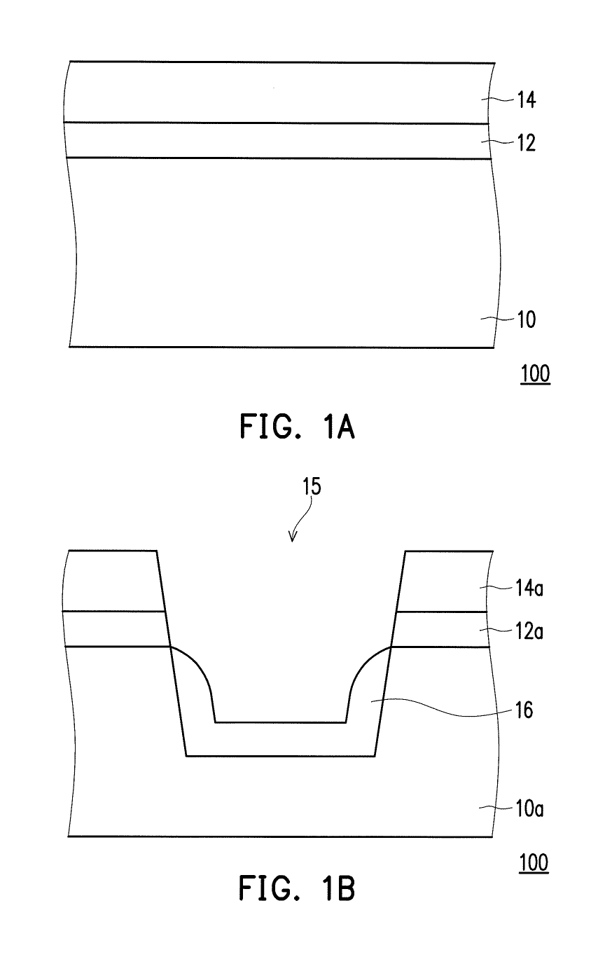

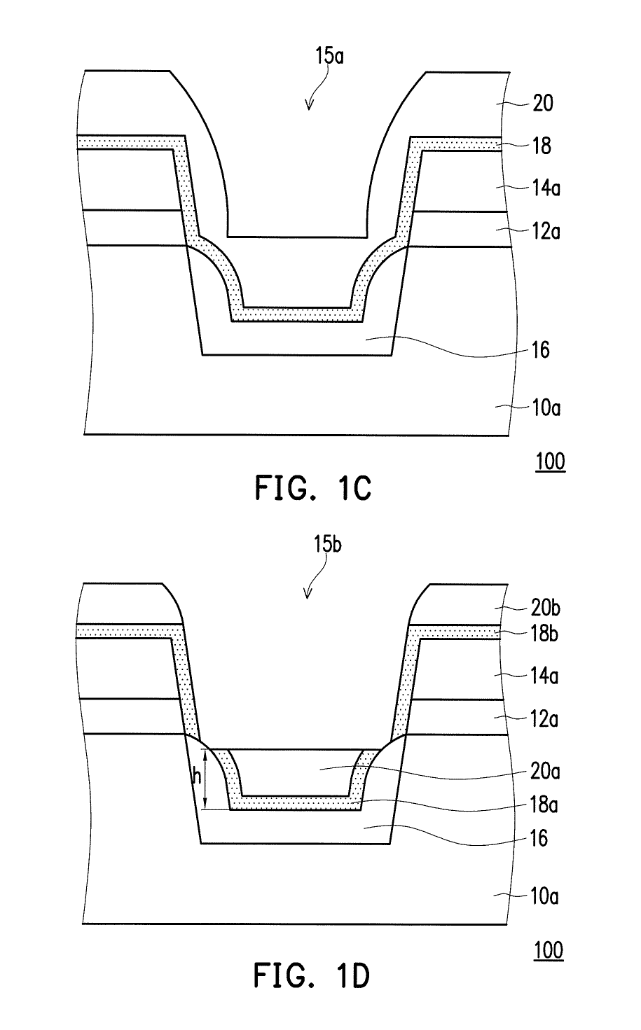

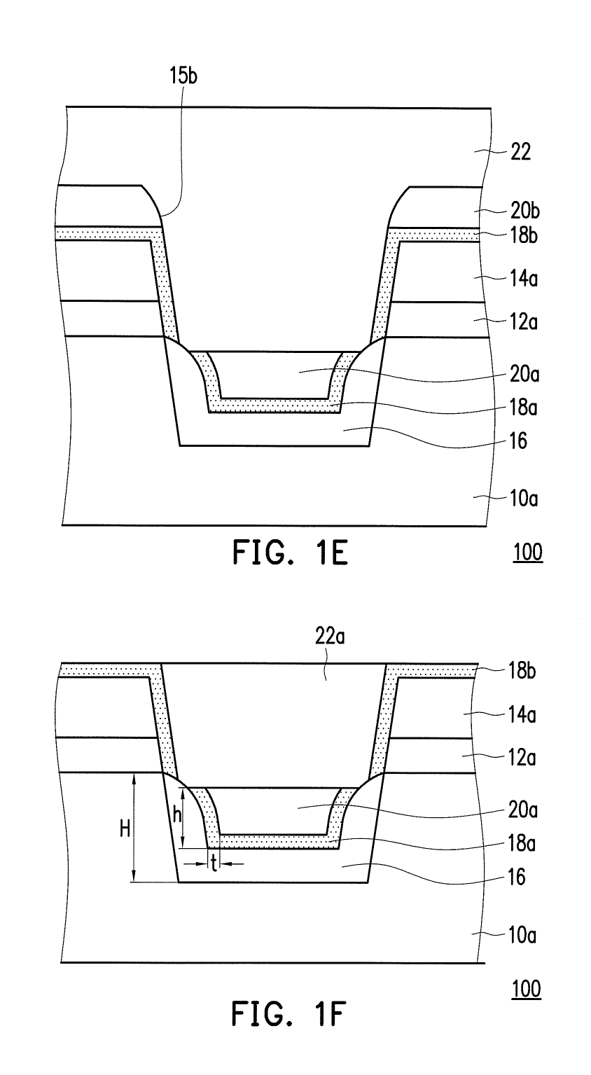

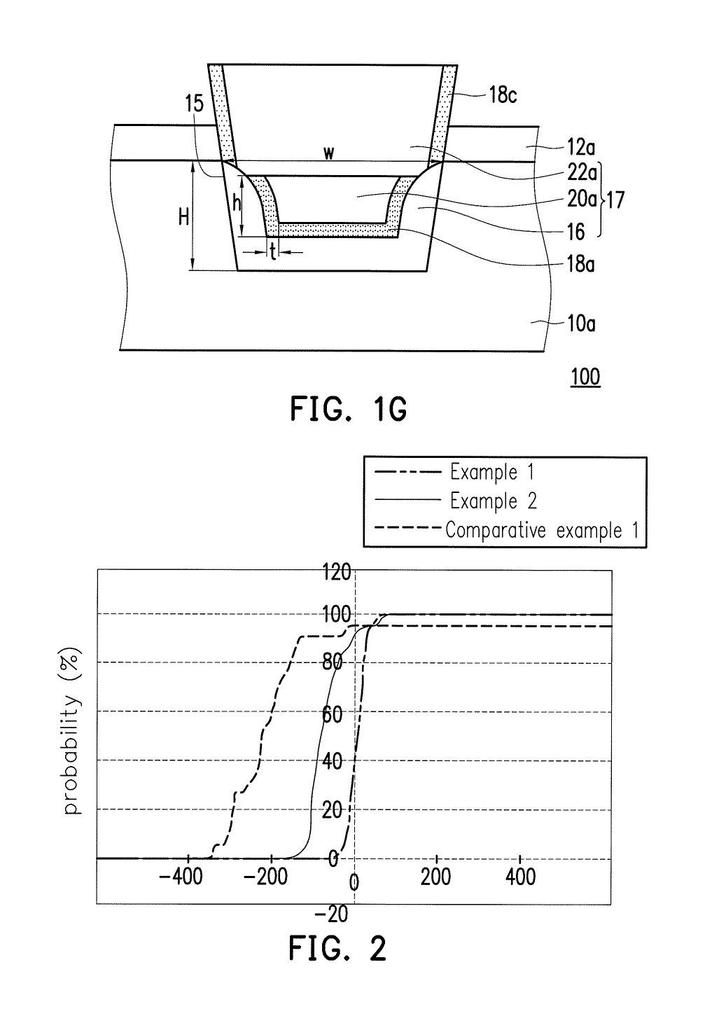

FIG. 1A to FIG. 1G are schematic cross-sectional views illustrating a method of fabricating an isolation structure according to an embodiment of the invention.

Referring to FIG. 1A, a substrate 10 is provided first, and a pad layer 12 and a hard mask layer 14 are formed on the substrate 10 sequentially. The substrate 10 may include a semiconductor material, an insulator material, a conductor material, or a combination thereof. A material of the substrate 10 is a material formed of at least one substance selected from a group consisting Si, Ge, SiGe, GaP, GaAs, SiC, SiGeC, InAs, and InP, for example, or any physical structure suitable for a fabricating process of the invention. The substrate 10 includes a single-layer structure or a multi-layer structure. In addition, a silicon on insulator (SOI) substrate may also be used. The substrate 10 is silicon or silicon germanium, for example.

A material of the pad layer 12 includes oxide, nitride, oxynitride, or a combination thereof, for example. A method of forming the pad layer 12 is thermal oxidation or a chemical vapor deposition (CVD), for example. The hard mask layer 14 includes a single-layer structure or a multi-layer structure, for example. A material of the hard mask layer 14 is different from the material of the pad layer 12. The material of the hard mask layer 14 is silicon oxide, silicon nitride, or other suitable materials, for example. A method of forming the hard mask layer 14 includes chemical vapor deposition.

Referring to FIG. 1B, a pattern process is performed to the hard mask layer 14 and the pad layer 12, so as to form a trench 15 in the substrate 10. A method of the pattern process is a lithography process and an etching process, for example. The etching process is a dry etching process, for example. The dry etching process may be a sputtering etching process or a reactive ion etching process, for example. A shape of the trench 15 may be in arbitrary shape, such as a V shape, a U shape, a rhombus shape, or a combination thereof.

Continuing to refer to FIG. 1B, forming a liner layer 16 on the trench 15 to cover a bottom surface and sidewalls of the trench 15. In an embodiment, the liner layer 16 only covers the bottom surface and portions of sidewalls of the trench 15. The portions of sidewalls intends to sidewalls of the substrate 10a located in the trench 15. In other words, sidewalls of the pad layer 12a and the hard mask layer 14a located in the trench 15 are not covered by the liner layer 16. However, the invention is not limited thereto. A material of the liner layer 16 includes silicon oxide, for example. A thickness of the liner layer is in a range of 10 angstroms to 1000 angstroms, for example. A method of forming the liner layer 16 is thermal oxidation or chemical vapor deposition, for example.

Referring to FIG. 1B and FIG. 1C, a buffer layer 18 is formed over the substrate 10a to cover a surface of the liner layer 16. In an embodiment, the buffer layer 18 covers the surface of the liner layer 16, a remaining surface of the trench 15, and a top surface of the hard mask layer 14a. In an embodiment, the buffer layer 18 conformally covers the surface of the liner layer 16, the remaining surface of the trench 15, and the top surface of the hard mask layer 14a. The remaining surface of the trench 15 includes the sidewalls of the pad layer 12a and the hard mask layer 14a located in the trench 15, for example. However, the invention is not limited thereto. A material of the buffer layer 18 may be any capable of being stress buffer materials. In an embodiment, a material stress of the buffer layer 18 is larger than a material stress of the liner layer 16. In some embodiments, the material of the buffer layer 18 includes silicon nitride, silicon oxynitride, or a combination thereof. The buffer layer 18 may be a single-layer structure or a multi-layer structure. The single-layer structure may be composed of a single material, or a gradual layer. In an exemplary embodiment, the material stress of the buffer layer 18 increases gradually from near the liner layer 16 to far from the liner layer 16. In another exemplary embodiment, the buffer layer 18 is a single-layer structure. The material of the buffer layer 18 is silicon nitride, for example. In yet another exemplary embodiment, the buffer layer 18 is a single-layer structure and a gradual layer, wherein a portion of the buffer layer 18 near the liner layer 16 is silicon oxynitride while a portion of the buffer layer 18 far from the liner layer 16 becomes silicon nitride. In yet another exemplary embodiment, the buffer layer 18 is a multi-layer structure, for example. The buffer layer 18 near the liner layer 16 is a silicon oxynitirde layer, for example, and the buffer layer 18 far from the liner layer 16 is a silicon nitride layer, for example. A method of forming a buffer layer 18 is chemical vapor deposition, for example.

Continuing to refer to FIG. 1C, a first insulation layer 20 is formed over the substrate 10a to cover a surface of the buffer layer 18. A material of the first insulation layer 20 includes oxides, spin-on dielectric (SOD) materials, or a combination thereof. In an exemplary embodiment, the material of the first insulation layer 20 is silicon oxide, for example. A thickness of the first insulation layer 20 is in a range of 500 angstroms to 3500 angstroms, for example. A method of forming the first insulation layer 20 is high density plasma chemical vapor deposition (HDP-CVD), spin on glass (SOG), or high aspect ratio process (HARP), for example. The material of the first insulation layer 20 is different from the material of the buffer layer 18. The material of the first insulation layer 20 may be the same as or different from the material of the liner layer 16. A density of the material of the first insulation layer 20 may be different from a density of the material of the liner layer 16. In some embodiments, the material of the first insulation layer 20 is the same as the material of the liner layer 16, but the forming methods thereof are different. In an exemplary example, a rate of forming a film (a deposition rate or a growth rate) of the first insulation layer 20 is larger than a rate of forming a film of the liner layer 16. In an exemplary example, the first insulation layer 20 is formed by chemical vapor deposition, and the liner layer 16 is formed by thermal oxidation.

Referring to FIG. 1C and FIG. 1D, an etching process is performed to remove the first insulation layer 20 and a portion of the buffer layer 18 located on the sidewalls of the trench 15a to expose a buffer layer 18b and a portion of sidewalls of the liner layer 16 on the sidewalls of the trench 15a. The etching process includes a dry etching process, a wet etching process, or a combination thereof, for example. An etching gas of the dry etching process includes nitrogen trifluoride (NF₃), for example. An etching liquid of the wet etching process includes phosphoric acid (H₃PO₄), hydrofluoric acid (HF), or a combination thereof, for example. In an embodiment, the wet etching process is a two-stage etching process, for example. In an exemplary embodiment, the two-stage etching process may be performed by a first etching using hydrofluoric acid to remove the first insulation layer 20 located on the sidewalls of the trench 15a, so as to expose the buffer layer 18. Then the two-stage etching process may be performed by a second etching using phosphoric acid to remove the portion of the buffer layer 18, so as to expose the portion of sidewalls of the liner layer 16 on the sidewalls of the trench 15b. The two-stage etching process can be performed by using various etching liquids having different etching selectivity ratio on the buffer layer 18 and the first insulation layer 20, so as to achieve a different etching rate on the sidewalls and the bottom portion. However, the invention is not limited thereto. In another embodiment, a photoresist (not shown) may be formed on a bottom surface of the trench 15a (i.e., the bottom surface of the first insulation layer 20 located in the trench 15a) first. Then an etching process is performed to remove the first insulation layer 20 and the portion of the buffer layer 18 located on the sidewalls of the trench 15a. Finally, the photoresist is removed.

As shown in FIG. 1D, after the above removal step, the buffer layer 18 may be divided into a buffer layer 18a and a buffer layer 18b. The buffer layer 18a covers the top surface and a portion of sidewalls of the liner layer 16 located in the bottom of the trench 15b. The buffer layer 18b covers the pad layer 12a and the hard mask layer 14a located on the sidewalls of the trench 15b and a top surface of the hard mask layer 14a. A space between the buffer layer 18a and the buffer layer 18b expose a portion of sidewalls of the liner layer 16. A shape of the buffer layer 18a may be a U shape or a V shape, for example. However, the invention is not limited thereto. Besides, after the removal step, the first insulation layer 20 may be divided into a first insulation layer 20a and a first insulation layer 20b. The first insulation layer 20a is located in the bottom of the trench 15b and covers the buffer layer 18a. The first insulation layer 20b covers the buffer layer 18b.

It should be noted that a height h of the buffer layer 18a (a height of the buffer layer 18a near the sidewalls of the trench 15b) may be regulated the process parameters of forming the first insulation layer 20 or the process parameters of the above removal step to achieve the desired height of the buffer layer 18a. In an embodiment, a top surface of the buffer layer 18a near the sidewalls of the trench 15 (i.e., two end points of the U shape or the V shape of the buffer layer 18a) lower a top surface of the substrate 10a. In this case, since the buffer layer 18a may not protrude from the top surface of the substrate 10a, the problems in bridge defects could be avoided.

Referring to FIG. 1E, a second insulation layer 22 is formed over the substrate 10a to cover a top surface of the first insulation layer 20a, a top surface of the buffer layer 18a, and a portion of sidewalls of the liner layer 16. In an embodiment, the portion of the sidewalls of the liner layer 16 intends to the exposed portions after the above removal step. In another embodiment, the second insulation layer 22 further includes covering sidewalls of the buffer layer 18b and a surface of the first insulation layer 20b. However, the invention is not limited thereto. In an embodiment, the trench 15b is fully filled with the second insulation layer 22. A material of the second insulation layer 22 includes oxides, spin-on dielectric materials, or a combination thereof, for example. In an exemplary embodiment, the material of the second insulation layer 22 is silicon oxide, for example. A thickness of the second insulation layer 22 is in a range of 2000 angstroms to 10000 angstroms, for example. A method of forming the second insulation layer 22 is high density plasma chemical vapor deposition, spin on glass, or high aspect ratio process. In an embodiment, the material of the second insulation layer 22 is the same as the material of the first insulation layer 20. In another embodiment, the material of the second insulation layer 22 is different from the material of the first insulation layer 20. However, the invention is not limited thereto.

Referring to FIG. 1F, the first insulation layer 20b and the second insulation layer 22 over the buffer layer 18b are removed, so as a top surface of the remaining second insulation layer 22a is substantially coplanar to a top surface of the buffer layer 18b covering the hard mask layer 14a. However, the invention is not limited thereto. A method of removing the first insulation layer 20b and the second insulation layer 22 over the buffer layer 18b is a planarization process, for example. A method of the planarization process is chemical mechanical polishing (CMP), for example.

Referring to FIG. 1G, the hard mask layer 14a is removed, and the buffer layer 18b over the pad layer 12a is removed to leave a buffer layer 18c. In an embodiment, a top surface of the second insulation layer 22a and a top surface of the buffer layer 18c are substantially non-coplanar to a top surface of the pad layer 12a. In other words, the top surface of the second insulation layer 22a and the top surface of the buffer layer 18c are higher than the top surface of the pad layer 12a. However, the invention is not limited thereto. A method of removing the hard mask layer 14a and the buffer layer 18b is an etching process, for example. The etching process is a wet etching process, for example. An etching liquid used for the wet etching process is hydrofluoric acid, for example.

In the following, the structure of the isolation structure of the invention is described with reference to FIG. 1G. As shown in FIG. 1G, the isolation structure 100 of the invention includes the buffer layer 18a and an encapsulation layer 17. The buffer layer 18a is located in the trench 15 of the substrate 10a. The encapsulation layer 17 is located in the trench 15 and encapsulates around the buffer layer 18a, wherein the buffer layer 18a is unexposed and is not in contacted with the trench 15. The material of the buffer layer 18a is different from the material of the encapsulation layer 17. In an embodiment, the encapsulation layer 17 further includes the liner layer 16, the first insulation layer 20a, and the second insulation layer 22a. The liner layer 16 is located on the bottom surface and the sidewalls of the trench 15, wherein the buffer layer 18a is located on the bottom surface and the portion of sidewalls of the liner layer 18a, wherein the another portion of sidewalls of the liner layer 16 is exposed. The first insulation layer 20a is located on the bottom surface and the sidewalls of the buffer layer 18a. The second insulation layer 22a is located on the top surface of the first insulation layer 20a, the top surface of the buffer layer 18a, and the another portion of sidewalls of the liner layer 16.

As shown in FIG. 1G, in an embodiment, a height H of the trench 15 (the height from the bottom of the trench 15 to the top surface of the substrate 12a) is in a range of 1000 angstroms to 10000 angstroms, for example. In another embodiment, the height h of the buffer layer 18a (the height of the buffer layer 18a near the sidewalls of the trench 15) is in a range of 1500 angstroms to 3000 angstroms, for example. In yet another embodiment, a thickness t of the buffer layer 18a is in a range of 100 angstroms to 200 angstroms, for example. In yet another embodiment, a width w of the trench 15 (the width of the trench located between the top surfaces of the substrate 12a) is in a range of 1800 angstroms to 3600 angstroms, for example. However, the invention is not limited thereto.

In an embodiment, a ratio of the height h of the buffer layer 18a and the thickness t of the buffer layer 18a is in a range of 10% to 90%, for example. In another embodiment, a ratio of the height h of the buffer layer 18a and the width w of the trench 15 is in a range of 20% to 90%, for example. In yet another embodiment, a ratio of the thickness t of the buffer layer 18a and the width w of the trench is in a range of 10% to 90%, for example. However, the invention is not limited thereto.

It should be noted that the height, the thickness, and the profile of the buffer layer may be achieved to the desired range by regulating the parameters. For example, the thicker of the buffer layer, the better to improve the problems in lattice dislocations when the thickness of the buffer layer is in a specific range. However, it may result reducing the filling-gap ability and causing the bridge defects when the thickness of the buffer layer is over the specific range. Furthermore, since the influence of the stress effects and the dimension effects, the width of the trench may also influence the thickness and the height of the buffer layer related to the improvement range of the problems such as lattice dislocations or bridge defects. Therefore, the height, the thickness, and the profile of the buffer layer of the invention may be regulated into a best range by following the above processes.

FIG. 2 is a leakage current test of isolation structures manufactured according to examples and comparative examples of the invention.

### Example 1

An isolation structure manufactured according to an embodiment of the invention includes the above liner layer and the above buffer layer between the substrate and the isolation layer.

### Example 2

An isolation structure of the example 2 is similar to the isolation structure of the above example 1, but the isolation structure of the example 2 only includes the above liner layer without including the above buffer layer between the substrate and the insulation layer.

### Comparative Example 1

An isolation structure of the comparative example 1 manufactured following the traditional manufacture methods excludes the above liner layer and the above buffer layer between the substrate and the isolation layer.

As shown in FIG. 2, the results of the leakage current of the example 1, the example 2, and the comparative example 1 are represented as curves in FIG. 2. The phenomenon of the leakage current of the isolation structures of the example 1 and the example 2 are smaller as compared to the isolation structure of the comparative example 1, wherein the phenomenon of the leakage current of the isolation structure of the example 1 is the smallest. In other words, the isolation structure includes the buffer layer between the substrate and the insulation layer that can be used to reduce the current leakage. Furthermore, since the material stress of the insulation layer is larger as compared to the substrate, its compress stress thereof is also larger. As such, the isolation structure having the liner layer in between the substrate and the buffer layer can erase a high compress stress of the insulation layer to enhance the layer adhesion therebetween. Therefore, the isolation structure including both the liner layer and the buffer layer between the substrate and the insulation layer can effectively reduce the current leakage.

The isolation structure of the invention and the method for fabricating the same may be adapted for any processes of the complementary metal oxide semiconductor integrated circuits, and the isolation structure may be a shallow trench isolation (STI) structure or a deep trench isolation (DTI) structure. However, the invention is not limited thereto.

In view of the foregoing, due to the isolation structure formed in the embodiments of the invention having the buffer layer with a larger material stress used as a stress buffer layer between the substrate and the isolation layer, in the subsequent high temperature process, such as an annealing or a thermal oxidation process, a leakage current arising from structure deformation due to a volume expansion of the insulation layer in the trench can be avoided. Furthermore, due to the buffer layer may reduce the aspect ratio of the trench, it may achieve a proper gap-filling ability. In addition, by regulating the parameters, a suitable height, thickness, and profile of the buffer layer of the invention may be formed. In this way, the problems in bridge defects may be avoided. Furthermore, the semiconductor devices with the isolation structure have the better electron carrier mobility. Therefore, the electrical performance and the yield of the semiconductor devices can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An isolation structure, comprising:
a buffer layer comprises a lower buffer layer and an upper buffer layer, wherein the lower buffer layer located in a trench of a substrate; and
an encapsulation layer comprises a first portion located in the trench and encapsulated around the lower buffer layer, and a second portion protruding from a surface of the substrate,
wherein the lower buffer layer is unexposed and is not in contact with the trench, and a material of the buffer layer is different from a material of the encapsulation layer,
wherein the upper buffer layer is located on sidewalls of the second portion of the encapsulation layer, and a space between the lower buffer layer and the upper buffer layer exposes the first portion of the encapsulation layer.

2. The isolation structure as claimed in claim 1, wherein a shape of the lower buffer layer is a U shape or a V shape.

3. The isolation structure as claimed in claim 1, wherein the buffer layer comprises a single-layer structure or a multi-layer structure.

4. The isolation structure as claimed in claim 1, wherein the material of the buffer layer comprises silicon nitride, silicon oxynitride, or a combination thereof.

5. The isolation structure as claimed in claim 1, wherein a ratio of a height of the lower buffer layer and a width of the trench is in a range of 20% to 90%.

6. An isolation structure, comprising:
a liner layer, located on a bottom surface and sidewalls of a trench of a substrate;
a lower buffer layer, located on a surface and a portion of sidewalls of the liner layer;
an upper buffer layer, located on an upper portion of sidewalls of the liner layer, wherein a space between the lower buffer layer and the upper buffer layer exposes other upper portion of sidewalls of the liner layer;
a first insulation layer, located on a surface and sidewalls of the lower buffer layer; and
a second insulation layer, located on a top surface of the first insulation layer, a top surface of the lower buffer layer, and the other upper portion of sidewalls of the liner layer,
wherein the upper buffer layer is located on sidewalls of the second insulation layer.

7. The isolation structure as claimed in claim 6, wherein a shape of the lower buffer layer is a U shape or a V shape.

8. The isolation structure as claimed in claim 6, wherein the buffer layer comprises a single-layer structure or a multi-layer structure.

9. The isolation structure as claimed in claim 6, wherein a material of the buffer layer is different from a material of the liner layer.

10. The isolation structure as claimed in claim 6, wherein a material stress of the buffer layer is larger than a material stress of the liner layer.

11. The isolation structure as claimed in claim 6, wherein the material of the buffer layer comprises silicon nitride, silicon oxynitride, or a combination thereof.

12. The isolation structure as claimed in claim 6, wherein a thickness of the buffer layer is in a range of 100 angstroms to 200 angstroms.

13. The isolation structure as claimed in claim 6, wherein a ratio of a height of the lower buffer layer and a width of the trench is in a range of 20% to 90%.

14. The isolation structure as claimed in claim 6, wherein a material of the first insulation layer and a material of the second insulation layer respectively comprise oxides, spin-on dielectric materials, or a combination thereof.

15. A method of fabricating an isolation structure, comprising:
forming a trench in a substrate;
forming a liner layer, wherein the liner layer covers a bottom surface and sidewalls of the trench;
forming a buffer layer, wherein the buffer layer covers a surface of the liner layer;
forming a first insulation layer, wherein the first insulation layer covers a surface of the buffer layer;
removing a portion of the first insulation layer and a portion of the buffer layer to expose a portion of sidewalls of the liner layer on the sidewalls of the trench; and
forming a second insulation layer, wherein the second insulation layer covers a top surface of the first insulation layer, a top surface of the buffer layer, and the portion of sidewalls of the liner layer.

16. The method of fabricating the isolation structure as claimed in claim 15, wherein a material stress of the buffer layer is larger than a material stress of the liner layer.

17. The method of fabricating the isolation structure as claimed in claim 15, wherein after removing the portion of the first insulation layer and the portion of the buffer layer, a ratio of a height of the buffer layer and a width of the trench is in a range of 20% to 90%.

18. The method of fabricating the isolation structure as claimed in claim 15, wherein a method to remove the portion of the first insulation layer and the portion of the buffer layer comprises a dry etching process, a wet etching process, or a combination thereof.

19. The method of fabricating the isolation structure as claimed in claim 18, wherein an etching gas of the dry etching process comprises nitrogen trifluoride (NF₃).

20. The method of fabricating the isolation structure as claimed in claim 18, wherein an etching liquid of the wet etching process comprises phosphoric acid (H₃PO₄), hydrofluoric acid (HF), or a combination thereof.
